(19) United States
(12) Patent Application Publication
(10) Pub. No.: US 2012/0288403 A1
(43) Pub. Date: Nov. 15, 2012

(54) GaAs SINGLE CRYSTAL WAFER AND METHOD OF MANUFACTURING THE SAME

(75) Inventor: Takashi KIMURA, Hitachi (JP)

(73) Assignee: HITACHI CABLE, LTD., Tokyo (JP)

(21) Appl. No.: 13/461,025

(22) Filed: May 1, 2012

(30) Foreign Application Priority Data
May 13, 2011 (JP) 2011-108237

(51) Int. Cl. C22C 28/00; C30B 15/30

(52) U.S. Cl. 420/579; 117/3

(57) ABSTRACT

The present invention provides a GaAs single crystal wafer and a method of manufacturing the same, wherein the wafer is characterized in that, when the strain in the radial direction in the GaAs single crystal wafer is expressed as Sr and the strain in the tangential direction on the circumference of the same is expressed as St, the residual stress in a wafer plane of the semi-insulating GaAs wafer denoted by |Sr−St| is smaller than 1.0×10⁻⁵ in the center area of such wafer plane and in that the wafer has such a region in which the value |Sr−St| is not smaller than 1.0×10⁻⁵ in the outer area and has such a region in which the value |Sr−St| is smaller than 1.0×10⁻⁵ in the direction [011] in the outer area of such wafer plane.

### TECHNICAL FIELD

The present invention relates to a new GaAs single-crystal wafer and a method of manufacturing the same.

### BACKGROUND ART

Semi-insulating GaAs single-crystal is manufactured typically with Liquid Encapsulated Czochralski Method (LEC Process) or Vertical Gradient Freezing Method (VGF Process).

JP05-339100A (patent literature 1) describes a compound semiconductor single crystal and a method of growing the same. The literature states: that the invented GaAs single crystal is manufactured through LEC Process and the residual strain of which is made to be 1×10⁻⁵ or smaller in average; that, in the invented crystal growing method, the temperature gradients within the crystal during crystal growing and while cooling after growth are maintained at the predetermined values and the rate of the crystal cooling and the speed of rotation during crystallization are maintained at the specified rates; that the single crystal manufactured thereby yields such a wafer as hardly cracks during treatments such as slicing and polishing including subsequent device-fabrication processes; and that no crystal defects such as a slipband (or a slip line) will appear in the thin-film crystal layer grown on a substrate that uses the invented single crystal.

JP2007-214368A (patent literature 2) describes a compound semiconductor wafer for Metal Organic Vapor Phase Epitaxial Method (MOVPE Process) and a method of manufacturing the same. The wafer defined therein is hard to generate a slipband (or a slip line) in its wafer-plane even if a rapid temperature variation is applied thereon, wherein the wafer is obtained through an epitaxial growth built on a concentrically bent wafer. The shape of such bent wafer is such that, when the wafer is placed with its surface upward on which surface an epitaxial layer such as AlGaAs and InGaAs is to be grown through MOVPE Process, the center portion of the wafer is lower and the circumference of the same is elevated.

JP2006-327879A (patent literature 3) has described a method of manufacturing compound semiconductor single crystal with LEC Process, wherein the polycrystallization is prevented by maintaining the shape of the portion of the compound semiconductor single crystal on the solid-liquid interface between the compound semiconductor and the melt of raw material being convex toward the melt.

In manufacturing single crystal with LEC Process, the dislocation, which is a cause of polycrystallization, propagates in the direction perpendicular to the solid-liquid interface. Therefore, when the shape of the solid-liquid interface is concave seeing from the melt side, dislocations aggregate resulting in occurrence of the polycrystallization. In consideration of this problem, various structures or growing conditions have been proposed regarding the shape of the solid-liquid interface during manufacturing so that the processing can be carried out with the shape of the solid phase being convex into the melt.

JP2008-174415A (patent literature 4) describes a semi-insulating GaAs single crystal wafer and a method of manufacturing the same. The literature states: that the invented GaAs single crystal manufactured through LEC Process is made to have such properties that, when a wafer is provided using such single crystal, the dislocation density of such wafer in its wafer plane is 30,000 to 100,000 count/cm²; that the residual stress |Sr−St| within such single crystal is made to be 1.8×10⁻⁵ or smaller; that the temperature gradient in the growing direction during the crystal growth is controlled 20 to 150 C°/cm; and that the invented semi-insulating GaAs single crystal wafer manufactured thereby generates no slipband (or a slip line) after annealing.

### DISCLOSURE OF INVENTION

After the above-stated semi-insulating GaAs single crystal was grown, the crystal is sliced to obtain a semi-insulating GaAs wafer substrate. On the wafer, a thin film of compound semiconductor such as AlGaAs and InGaAs is formed by epitaxial growth using MOVPE Process or Molecular Beam Epitaxial Growth Method (MBE Process). After that processing, electronic devices or light receiving/emitting elements are manufactured using the wafer employing various techniques such as lithography and etching.

It should be reminded that the lattice constant and the thermal expansion coefficient of thin film of compound semiconductors like AlGaAs and InGaAs grown by epitaxial growth are different from those of the base wafer of such as GaAs because their compositions are different each from the other. Because of this, an epitaxial wafer has a high strain, which causes the wafer to bend into a convex shape as a whole.

Further, the semi-insulating GaAs wafer is exposed to high temperatures several times during above-stated manufacturing process. In the epitaxial growth in MOVPE Process for example, the process includes such a treatment as heats the wafer to about 800° C. to produce the epitaxial growth followed by cooling; this means that the wafer itself is exposed to a high temperature.

FIG. 4 is a schematic plan view of a single crystal wafer that has a slipband (or slip line) after annealing. A compound semiconductor wafer, on which an epitaxial layer having a lattice constant different from that of the wafer is formed, has a not little curvature. Therefore, at the time of temperature fall after the epitaxial growth or at the time of temperature rise during the wafer annealing after the epitaxial growth, a linear seam, namely a slipband 16, appears on a wafer 15 stretching from the outer periphery of the wafer 15 toward the crystal orientation, as illustrated in FIG. 4, to release the curvature thereof namely the lattice strain.

If a sharp temperature variation is applied on the wafer 15, a part of the crystal moves to release the internal strain stated above. This movement produces height difference on the crystal plane causing level difference on the wafer surface. This level difference is the slipband. The slipband appears on the outer periphery, the open end of the crystal, and its level difference propagates toward the center of the wafer. Thus, the slipband appears as the linear seam that stretches from the outer periphery toward the center.

About the center of the wafer, the device-forming areas are located. If therefore the slipband reaches the device area, a problem arises in that the device may have fault such as circuit break.

To suppress the occurrence of the slipband, it is effective to reduce the rate of temperature fall after the epitaxial growth and the pace of temperature rise/fall during wafer annealing. However, the reduction of the rate of or the pace of temperature rise/fall is difficult in practicability, because the temperature change at a higher speed is advantageous for controlling or stabilizing the device characteristics.

In consideration of this problem, the art defined in Patent Literature 2 suppresses the occurrence of the slipband by correcting the bend of the wafer that appears after the epitaxial growth. The correction is rendered by use of a concentrically bent concave wafer. Such wafer is obtained by making in advance the form of the compound semiconductor wafer for epitaxial growth into such a concentrically bent concave shape that, when the wafer is placed with its surface upward on which surface an epitaxial layer is to be grown, the center portion of the wafer is lower and the circumference of the same is elevated.

However, the upsizing of the GaAs wafer over 150 mm in diameter brings problem in that such large-sized wafers, even though the shape is bent, still tends to have the slipband that stretches from the outer periphery of the wafer toward its center as the heat treatment or epitaxial growth progresses.

This is attributable to the fact that the upsizing of wafers in diameter makes it difficult to maintain the temperature within the wafer plane at uniform distribution. As a consequence to this, correcting the strain by giving the wafer a bent shape is not enough. Because, non-uniform temperature distribution across the center portion to the outer periphery generates a thermal stress, which releases the strain resulting in occurrence of the slipband stretching from the outer periphery of the wafer toward its center. This behavior of slipband occurrence has been found in many manufacturing methods for GaAs single crystal, not only in LEC Process or VB Process. Therefore, this problem can be common to all the GaAs wafers of which diameter is over 150 mm.

In Patent Literatures 1 and 4, the reduction of the residual stress in the wafer plane is the major premise of the means for suppressing the occurrence of the slipband. However, residual stress is unavoidably left in the crystal in the case of manufacturing GaAs single crystals having diameters over 150 mm because of the temperature difference between the outer area and the center area of the crystal under growth. One of methods for releasing this residual stress is to produce the dislocation by a heat treatment that gives a steep temperature gradient. But GaAs wafers of high dislocation density are understood to be a material that is hard to apply to so-called “vertical devices”.

In Patent Literature 3, what has been mentioned is the prevention of polycrystallization in manufacturing compound single crystal with LEC Process. Nothing has been mentioned in terms of the occurrence of slipband or the suppression thereof.

An object of the present invention is to provide, overcoming drawbacks of conventional arts stated above, a large-diameter GaAs single crystal wafer that generates no slipband and a method of manufacturing the same. The invented method lightens effects of the wafer bend and the degree of nonuniformity of temperature distribution in the wafer plane on the heat treatment in the device manufacturing process that uses GaAs single crystal wafer and thereby the manufactured wafer generates no slipband even though the releasing of the residual stress by introduction of dislocation technique for elimination of occurrence of the slipband is not applied.

The present invention provides a GaAs single crystal wafer that is characterized in that, when the strain in the radial direction in the GaAs single crystal wafer is expressed as Sr and the strain in the tangential direction on the circumference of the same is expressed as St, the absolute value of the residual stress in a wafer plane of the wafer denoted by |Sr−St| is smaller than 1.0×10⁻⁵ in the center area of such wafer plane and in that the wafer has such a region in which the value |Sr−St| is 1.0×10⁻⁵ or more in the outer area of such wafer plane and has such a region in which the value |Sr−St| is smaller than 1.0×10⁻⁵ in the direction [011] in the outer area of such wafer plane.

A GaAs single crystal wafer by the present invention is preferably to have a dislocation density (hereinafter referred to as EPD) of 30,000 count/cm² or smaller in its wafer plane and is preferably to have a diameter of 100 mm or more.

In the present invention, each of the regions in a round wafer is defined as follows. When the radius of the round wafer is divided into three equal portions, the region spreading outwards from the two-thirds division point from the center is defined as an outer area and the region inside such outer area is defined as a center area. The present invention is not concerned with such a single crystal wafer as has an area of high residual stress around its center region, because such wafer generates the slipband at a high rate in subsequent processes. Such single crystal wafer includes a wafer having the outer area, of which |Sr−St| is 1.0×10⁻⁵ or more, spreading further-inwardly and a wafer having an area of high residual stress around its center region even though the area is not a continuation of the outer area.

The present invention provides a method of manufacturing a GaAs single crystal wafer of GaAs solid phase using a setup comprising a crucible, which is mounted on a susceptor, being accommodated in a container and a melt of GaAs, which is melted by heat, and a liquid sealer being contained in the crucible, wherein the method applies a technique comprising keeping a seed crystal kept touching the liquid phase of the melt of GaAs and moving the seed crystal and the crucible relatively, wherein the method is characterized in that the shape of the solid phase on the solid-liquid interface between the solid phase and the liquid phase under the manufacturing the single crystal is made convex toward the liquid phase side, the degree of convex of such shape (a ratio of the length T1, which is the distance from the interface between the melt and the liquid sealer to the top end of the convex, and the diameter of the single crystal T2, namely T1/T2) is made to be 0.25 or more, the crystal growth rate V1 in the direction of the relative movement on the solid-liquid interface is made to be 4 mm/hr to 7 mm/hr; and the cooling rate V2 of the solid phase is made to be 5° C./hr or lower.

Thereby, this manufacturing method obtains a GaAs single crystal wafer having features such that, when the strain in the radial direction is expressed as Sr and the strain in the tangential direction on the circumference is expressed as St, the value of the residual stress in a wafer plane of the semi-insulating GaAs wafer denoted by |Sr−St| satisfies |Sr−St|<1.0×10⁻⁵ in the center area of wafer plane of the wafer and such that the wafer has such a region as satisfies |Sr−St|≧1.0×10⁻⁵ in the outer area of such wafer plane and has such a region as satisfies |Sr−St|<1.0×10⁻⁵ in the direction [011] in the outer area of such wafer plane. Therefore, combining the plane (001) and the direction [010], of which residual strains are high, with the direction [011], of which residual strain is small, lightens effects of the wafer bend and the degree of uniformity of temperature distribution in the wafer plane on the heat treatment in the device manufacturing process that uses GaAs single crystal wafer. Thus, the invented method realizes a GaAs single crystal wafer having the feature stated above that generates no slipband even though the releasing of the residual stress by introduction of dislocation technique for elimination of occurrence of the slipband is not applied.

The present invention provides a semi-insulation GaAs single crystal wafer obtained by slicing a growth-completed semi-insulating GaAs single crystal, which is characterized in that, when the strain in the radial direction in the GaAs single crystal wafer is expressed as Sr and the strain in the tangential direction on the circumference of the same is expressed as St, the value of the residual stress in a wafer plane of the semi-insulated GaAs wafer denoted by |Sr−St| satisfies |Sr−St|<1.0×10⁻⁵ in the center area of wafer plane of the wafer and in that the wafer has such a region as satisfies |Sr−St|≧1 1.0×10⁻⁵ in the outer area of such wafer plane and has such a region as satisfies |Sr−St|<1.0×10⁻⁵ in the direction [011] in the outer area of such wafer plane and in that the dislocation density (EPD) is preferably 30,000 count/cm² or smaller in its wafer plane.

Now the following explains a method of measuring optically the residual stress in a wafer plane using photoelastic phenomenon.

The photoelastic phenomenon is a phenomenon in which an isotropic and homogeneous elastic material optically exhibits the property of birefringence (in which material exhibits different refractive index depending on the polarization orientation of light) on application of external force; that is, when external force is applied on such material, stress appears therein causing the material to behave temporarily as an anisotropic material exhibiting the property of birefringence.

In the measuring method with the photoelastic phenomenon, an internally-stressed crystal is irradiated with infrared light and the angle of rotation of the polarization plane of the transmitted infrared light is measured to determine the stress. The incident infrared light travels in birefringence mode due to the residual stress. Accordingly, a phase difference of lights appears, because the refractive index differs depending on the direction of the polarization plane and accordingly the travelling speeds of lights differ. As a result of this, the polarization plane of the transmitted light rotates that the azimuth of principal vibration and the phase difference determines, wherein the extent of the angle of rotation of the polarization plane is dependent on the magnitude of the residual stress in the wafer, as the principle stated above teaches. Thus, detecting the rotation angle of the polarization plane measures the amount of the residual stress.

In the present invention, the residual stress in the GaAs wafer plane |Sr−St| is defined as a calculated absolute value of the difference between Sr, which denotes the radial strain on the cylindrical coordinates, and St, which denotes the tangential strain on the circumference.

That is, the residual stress |Sr−St| is expressed by the following equation.

$$\vert Sr - St \vert = \frac{λ δ}{π {dn}_{0}^{3}} {\{ {( \frac{cos 2 φ}{{p}_{11} - {p}_{12}} )}^{2} + {( \frac{sin 2 φ}{{p}_{44}} )}^{2} \}}^{1 / 2}$$

(λ: Wave length of source light, d: Thickness of wafer, n0: Refraction index, δ: Phase difference due to birefringence in sample, φ: Azimuth of principal vibration; P11, P12, P44: Photoelastic constants)

As equation given above clearly shows, measuring the phase difference δ and azimuth of the principal vibration φ permits calculating the residual stress in the wafer |Sr−St|.

It should be noted that Patent Literature 4 has stated that the critical point of the occurrence rate of slipband is |Sr−St|=1.0×10⁻⁵. However, a further study by the inventors of the present invention has found a fact that, when a wafer is a semi-insulating GaAs wafer having a region that satisfies |Sr−St|<1.0×10⁻⁵ in the direction [011] in the center area and in the outer area of the wafer plane, the occurrence of the slipband is controlled even though the value |Sr−St| is in excess of 1.8×10⁻⁵ in the plane (001) or in the direction [010].

As a consequence of this, realization of a GaAs wafer, which generates no slipband even though the dislocation technique is not employed, becomes practicable.

As stated above, the present invention is able to form, on the semi-insulating GaAs wafer manufactured controlling the degree of convex (T1/T2) on the solid-liquid interface to be 0.25 or more, such regions that the residual stress |Sr−St| in the wafer plane is less than 1.0×10⁻⁵ in the center area thereof and is 1.0×10⁻⁵ or more in the outer area thereof.

Further, the present invention is able to form such regions that the residual stress |Sr−St| in the semi-insulating GaAs wafer plane under manufacturing is less than 1.0×10⁻⁵ in the direction [011] in the outer area thereof by controlling the crystal growth rate V1 in the direction along the crystal column on the solid-liquid interface to be 4 mm/hr to 7 mm/hr. Because the crystal growth rate strongly influences the orientation of crystal, the slower the crystal growth rate is, the more uniformly crystal tends to orient the stress. That is, bringing the crystal growth rate high enables the residual stresses to be biased toward a specific direction. However, if the residual stress is too large, the introduction of the dislocation occurs to release the stress. Therefore, the residual stress |Sr−St| in the wafer plane can be made less than 1.0×10⁻⁵ in the direction [011] in the outer area thereof and not less than 1.0×10⁻⁵ in the plane (001) and in the direction [010] by controlling the crystal growth rate V1 in the direction along the crystal column on the solid-liquid interface to be 4 mm/hr to 7 mm/hr at the time of crystal growth, manipulating the biasing of the residual stress with the occurrence of dislocation being controlled. In this technique however, it is necessary to control the crystal cooling rate V2 of the crystal so grown is to be 5° C./hr or slower.

Cooling a crystal causes temperature difference between the surface and the inside thereof since the crystal is cooled from its periphery; therefore, cooling produces thermal stress in the crystal. This means that slowing the crystal cooling rate suppresses production of thermal stress during cooling process preventing introduction of dislocation for stress releasing.

### Advantages of the Invention

The present invention is able to provide a large-diameter GaAs single crystal wafer that generates no slipband and a method of manufacturing the same. The invented method lightens effects of the wafer bend and the degree of uniformity of temperature distribution in the wafer plane on the heat treatment in the device manufacturing process that uses GaAs single crystal wafer and thereby the manufactured wafer generates no slipband even though the releasing of the residual stress by introduction of dislocation technique for elimination of occurrence of the slipband is not applied.

### BRIEF DESCRIPTION OF DRAWINGS

FIG. 1 is a schematic diagram of a semi-insulating GaAs single crystal manufacturing apparatus in the present invention, wherein the apparatus manufactures a semi-insulating GaAs single crystal using the LEC Process.

FIG. 2 is a schematic diagram of the solid-liquid interface that is an interface between the crystal, the solid phase of the on-growing crystal, and its melt in the manufacturing method of compound semiconductor single crystal by the present invention.

FIG. 3 is a schematic plan view of a single crystal wafer having the residual stress pattern, which is an object of the present invention.

FIG. 4 is a schematic plan view of a single crystal wafer that represents aspects of occurrence of the slipband after the single crystal wafer annealing in a comparison example.

### MODE FOR CARRYING OUT THE INVENTION

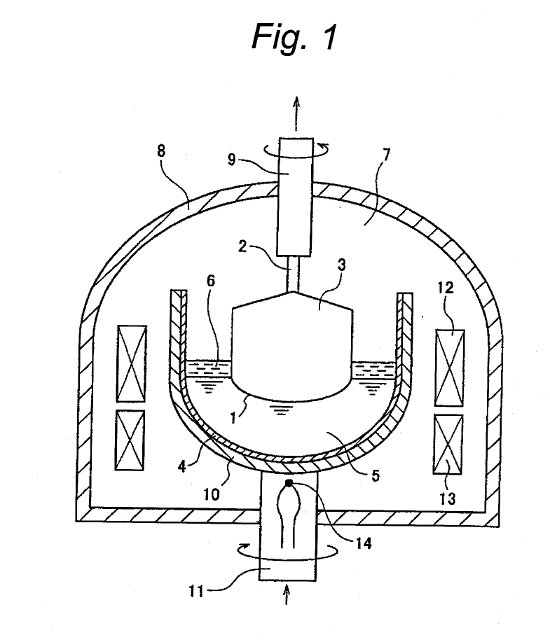

FIG. 1 is a cross sectional view of a GaAs single crystal manufacturing apparatus that manufactures semi-insulating GaAs single crystal using LEC Process. As FIG. 1 illustrates, in a growth furnace comprised of a high pressure vessel 8, which is a furnace body filled with inert atmosphere gas 7, a pull-up shaft (a top shaft) 9 is provided for pulling up single crystal and a seed (a seed crystal) 2 is attached at the toe of the pull-up shaft 9. The pull-up shaft 9 penetrates into the inside of the furnace from the top part of the growth furnace to confront a crucible 4. The crucible 4 is supported on a pedestal (bottom shaft) 11 sandwiching a susceptor 10 therebetween. In the crucible 4, a raw material 5 such as substances of group III and group V, which will become a single crystal 3, and a liquid sealant 6 such as B₂O₃ are charged. The pedestal 11, being aligned with the pull-up shaft 9, penetrates into the inside of the growth furnace from the bottom thereof. The susceptor 10 is fixed on the top end of the pedestal 11. Each of the pedestal 11 and the pull-up shaft 9 is rotated by a revolver (not illustrated) and raised or lowered by an elevating device (not illustrated).

In the growth furnace, an upper heater 12, a lower 13, and a temperature controller (not illustrated) for controlling the temperatures of the upper heater 12 and the lower heater 13 are provided as a heating means for melting the raw material 5 and the liquid sealant 6. In the pedestal 11, a thermocouple 14 is installed as the means for sensing the temperatures of the raw material 5 in the crucible 4 and the liquid sealant 6. The upper heater 12 and the lower heater 13 are arranged inside the growth furnace concentrically surrounding the susceptor 10 on its circumference. The thermocouple 14 is installed upper-inside of the shaft of the pedestal 11. The upper heater 12, which heats the crucible 4, works mainly for controlling the diameter of crystal; the lower heater 13 works mainly for controlling the shape of the solid-liquid interface.

In manufacturing a GaAs single crystal, the inside of the furnace is first maintained being filled with inert gas atmosphere of a predetermined pressure. In the case where substances of group III and group V are charged in the crucible 4, the pressure of the inert gas is regulated at such a level that the dissociation of substances of group V from the raw material 5 will be prevented. Next, the temperature controller activates the upper heater 12 and the lower heater 13. When the heating by the upper heater 12 and the lower heater 13 cause the temperature of the crucible 4 to reach the melting temperature of the liquid sealant 6, the liquid sealant 6 melts. When the temperatures of the upper heater 12 and the lower heater 13 reach the melting temperature of the raw material 5, the raw material 5 melts. At this instance, the surface of the melt of the raw material is covered with the liquid sealant 6, because the specific gravity of the melt of the raw material 5 is heavier than that of the liquid sealant 6 in general. Thus, the dissociation of elements of group V from the melt of the raw material 5 is prevented.

Growing the crystal is conducted as follows: The seed 2 attached at the toe of the pull-up shaft 9 is made to contact the melt of the raw material 5; and maintaining this state, the seed 2 is then pulled up slowly gradually lowering the temperatures of the upper heater 12 and the lower heater 13 by the feedback control rendered from the temperature controller. Thereby, the crystal grows and the single crystal 3 thus grown is pulled up passing through the liquid sealant 6. During the growing of the crystal, non-oxidizing gas is blown from the head portion of the crystal to control the axial gradient of the temperature. In the blowing operation of non-oxidizing gas, the blowing area and the gas temperature are properly regulated together with the gas flow rate.

On the other hand, as the crystal growth advances, the quantity of the melt in the crucible 4 reduces, which naturally causes the liquid level of the melt to be low. This lowering in the liquid level alters the positional relationship between the growing surface of the crystal and the heaters, namely the upper heater 12 and the lower heater 13, making maintaining the efficient heating the melt difficult. Therefore, a control is performed, wherein the amount of the liquid level lowering is calculated based on the amount of crystal growth, and the elevating device is controlled to gradually elevate the pedestal 11 so that the position of the crucible 4 is regulated to compensate such amount of lowering, thereby the control works so that the liquid level of the melt will be adjusted always at a proper position with respect to heating zones of the upper heater 12 and the lower heater 13.

The inventors manufactured a GaAs single crystal using a GaAs single crystal manufacturing apparatus that uses LEC Process illustrated in FIG. 1. 40,000 g of GaAs polycrystal and 2,500 g of boron trioxide as the liquid sealer 6 were charged in the crucible 4 of pyrolytic boron nitride (PBN). The crucible 4 was then placed in the high pressure vessel 8 and inside the vessel was filled with the inert atmosphere gas 7 to a pressure of 9.0 kg/cm². After the inert gas filling, the upper heater 12 and the lower heater 13 were activated to heat and melt the GaAs polycrystal and the boron trioxide. The temperature regulation and the seed crystal addition were performed to grow a crystal 3, of which diameter was 150 mm, controlling the degree of convex of the solid phase on the solid-liquid interface by regulating the upper heater 12 and the lower heater 13; thus, a GaAs single crystal having an entire length of 300 mm was grown.

The GaAs single crystal manufacturing apparatus in the embodiment of the present invention is comprised of: the high pressure vessel 8 that is the furnace body, the pull-up shaft (the top shaft) 9 having the seed crystal 2 for pulling up single crystal, the crucible 4 that is the container for the melt of the raw material 5 and the liquid sealant 6, the pedestal 11 that supports the crucible 4, the upper heater 12 that heats the crucible 4 and controls mainly the diameter of the crystal, and the lower heater 13 that controls mainly the shape of the solid-liquid interface.

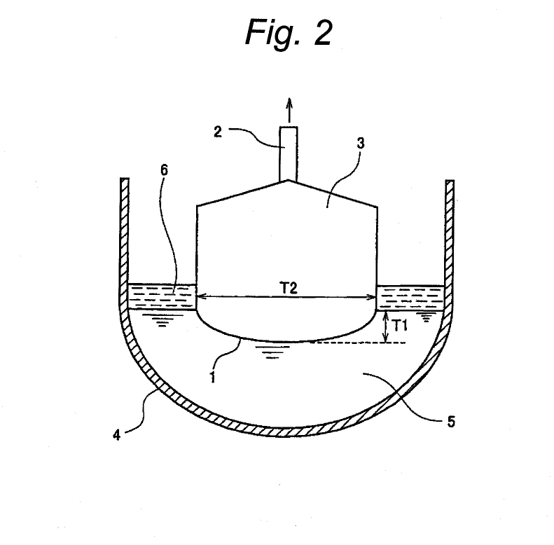

FIG. 2 illustrates the shape of the solid phase on the interface between the solid phase and liquid phase (solid-liquid interface) while manufacturing GaAs single crystal in an embodiment of the present invention, wherein the solid phase describes a convex toward the melt side. In the embodiment, the degree of convex of such shape (a ratio of the length T1, which is the distance from the interface between the melt and the liquid sealer to the top end of the crystal on the melt side, and the diameter of the crystal T2, namely T1/T2) was varied from 0.15 to 0.35.

The dislocation, which is the cause of polycrystallization, propagates in the direction perpendicular to the soli-liquid interface. Therefore, when the shape of the solid phase on the solid-liquid interface is concave seeing from the melt side, dislocations aggregate resulting in occurrence of the polycrystallization. In consideration of this problem, LEC Process in the embodiment of the present invention treats the material in such a condition that the shape of the solid phase on the solid-liquid interface during manufacturing the crystal is made to be convex toward the liquid phase namely the melt side.

In the embodiment of the present invention, crystals were manufactured varying conditions, wherein the crystal growth rate V1 in the direction of the crystal column on the solid-liquid interface is varied from 3 mm/hr to 8 mm/hr, and the crystal cooling rate after growth V2 is varied from 2 to 6° C./hr.

In the embodiment of the present invention, the degree of convex of the shape (a ratio of the length T1, which is the distance from the interface between the melt and the liquid sealer to the top end of the crystal on the melt side, and the diameter of the crystal T2, namely T1/T2) at the time of growth of GaAs single crystal was controlled between 0.25 and 0.35, the crystal growth rate V1 in the direction of the crystal column on the solid-liquid interface was controlled between 4 mm/hr and 7 mm/hr, and the crystal cooling rate after growth V2 was controlled between 2 and 5° C./hr. By applying combination of these condition-controlled three parameters (namely, the degree of convex of shape, the crystal growth rate, and the crystal cooling rate), the occurrence of dislocation was manipulated so that the biasing of the residual stress will be controlled. Thereby, the embodiment of the present invention attained a wafer such that the residual stress |Sr−St| in its wafer plane satisfies |Sr−St|<1.0×10⁻⁵ in the center area thereof, |Sr−St|≧1.0×10⁻⁵ in the outer area of such wafer plane, |Sr−St|<1.0×10⁻⁵ in the direction [011] in the outer area of such wafer plane, and |Sr−St|≧1.0×10⁻⁵ in the plane (001) and in the direction [010].

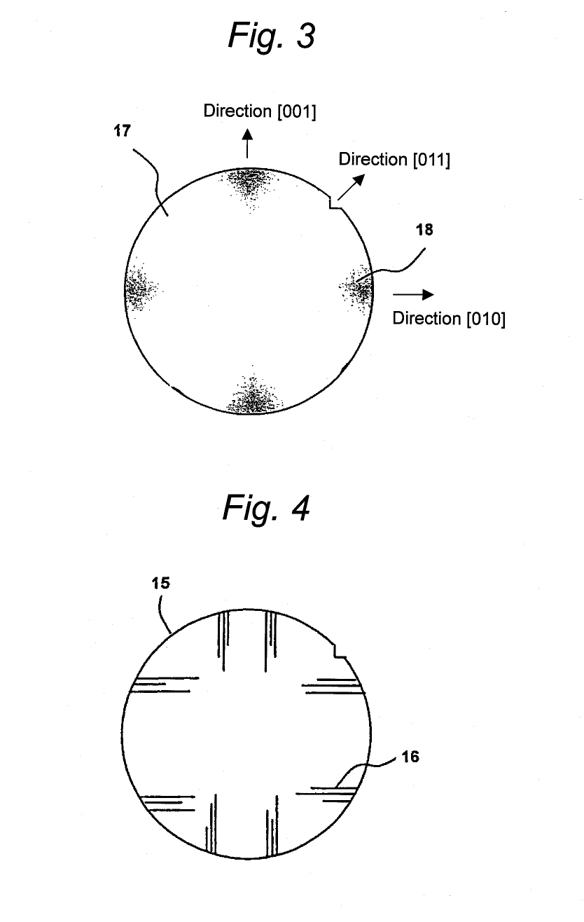

FIG. 3 is a schematic plan view of a single crystal wafer having a residual stress pattern, which is an object of the present invention. As FIG. 3 illustrates, the residual stress pattern, which is an object of the present invention, has a region 17 in which |Sr−St| in the center area of the wafer plane is smaller than 1.0×10⁻⁵ and a region 18 in which |Sr−St| is not smaller than 1.0×10⁻⁵. Regions 18 are formed on a single crystal wafer at an interval of 90-degree, wherein each of regions 18 is formed in a location within the outer one-third portion of the outer area, being given a sector-like shape spreading toward outside having a central angle of approximately 45-degree or narrower.

In the embodiment of the present invention, various types of semi-insulating GaAs single crystal wafers were manufactured. The wafers manufactured were then examined for their properties: whether the residual stresses and EPDs in those semi-insulating GaAs single crystal wafers satisfied the requirements of the present invention in terms of the plane shape, and the occurrence rate of slipband after the annealing of such semi-insulating GaAs single crystal wafer. The thickness of the examined semi-insulating GaAs single crystal wafer was 625 μm. The dislocation density (EPD) was determined counting the number of dislocations per pit-unit area on the wafer that appeared after the etching treatment.

Table 1 indicates the results of the examination at the crystal cooling rate of 2° C./hr, Table 2 at the crystal cooling rate of 4° C./hr, and Table 3 at the crystal cooling rate of 6° C./hr. The upper-half of each cell in tables, at which the parameter columns for the degree of convex of the solid-liquid interface 0.15 to 0.35 and the parameter lines for the crystal growth rate of 3 mm/hr to 8 mm/hr intersect, lists the yield rate of the wafer that satisfies the requirements by the present invention; and the lower half of the same cell lists the occurrence rate of slipband.

TABLE 1

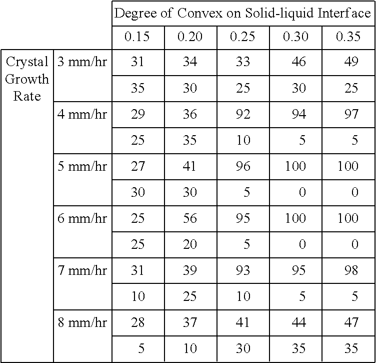

(FAX [symbol] [symbol] [symbol] [symbol] )

TABLE 2

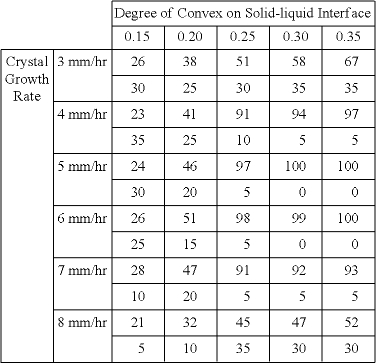

TABLE 3

| | | Degree of Convex on Solid-liquid Interface | | | | |
|---|---|---|---|---|---|---|
| | | 0.15 | 0.20 | 0.25 | 0.30 | 0.35 |
| Crystal | 3 mm/hr | 28 | 33 | 37 | 32 | 35 |
| Growth | | 25 | 20 | 20 | 20 | 25 |
| Rate | 4 mm/hr | 34 | 31 | 67 | 82 | 77 |
| | | 20 | 25 | 30 | 25 | 25 |
| | 5 mm/hr | 29 | 27 | 71 | 89 | 88 |
| | | 25 | 25 | 25 | 15 | 15 |
| | 6 mm/hr | 19 | 37 | 74 | 87 | 85 |
| | | 20 | 15 | 25 | 15 | 15 |
| | 7 mm/hr | 23 | 27 | 77 | 82 | 84 |
| | | 5 | 10 | 25 | 20 | 20 |
| | 8 mm/hr | 19 | 24 | 29 | 34 | 28 |
| | | 5 | 5 | 15 | 25 | 30 |

As can be known from Tables 1 to 3, those cells in the tables, in which 90% or more of samples were produced satisfying the requirement by the present invention, are shaded. Samples listed in such shaded cells show that their degrees of convex on the solid-liquid interface are 0.25 to 0.35 for both the crystal cooling rates of 2° C./hr and 4° C./hr under the crystal growth rates of 4 mm/hr to 7 mm/hr; and the occurrence rate of slipband of them are as low as 10% or less.

This means that the semi-insulating GaAs single crystal wafer in the embodiment of the present invention has features such that the residual stress |Sr−St| satisfies |Sr−St|<1.0×10⁻⁵ in the center area of wafer plane of the wafer; such that the wafer has such a region as satisfies |Sr−St|≧1.0×10⁻⁵ in the outer area of such wafer plane and has such a region as satisfies |Sr−St|<1.0×10⁻⁵ in the direction [011] in the outer area of such wafer plane; such that the occurrence rate of slipband is 10% or less; and such that the dislocation density (EPD) is 1000 count/cm², which is smaller than 30,000 count/cm².

On the other hand, there were some samples that exhibited an occurrence rate of slipband as low as 5% although some of their manufacturing conditions partly differed from the conditions that the present invention defined as above. In this situation, the partly-different manufacturing conditions under which such samples were manufactured are such that the crystal growth rates and the degree of convex were outside the ranges defined by the invention although the crystal cooling rate was 2° C./hr or 4° C./hr as defined by the invention, or such that the degrees of convex of the shape of solid-liquid interface were within 0.15 to 0.35 and the crystal grow rates were within 3 mm/hr to 8 mm/hr as defined by the invention but the crystal cooling rate was 6° C./hr. However, the yield (or acceptability) of such wafers has not reached 90% with respect to the residual stress requirement previously stated as an object of the present invention. Further, application of them to the vertical devices was difficult since their dislocation densities (EPDs) were over 100,000 count/cm².

Universal hardness of the GaAs single crystal wafer in the embodiment of the present invention is 4,300 N/mm² (MPa) or more in its outer area and is 4,000 N/mm² (MPa) in its center area and in the direction [011] thereof; these hardness are higher than the hardness of a 4-fold symmetry area. In determination the universal hardness, a micro hardness tester “Fischer Scope H-100” (Fischer Instruments K.K.) was used. This tester determines the micro hardness of a specimen based on a calculation applied to the area of a dent and its depth produced on the specimen under test by pressing an indenter like a square pyramid, or a triangular pyramid, into the specimen.

As described in the explanation of the embodiment of the present invention, in manufacturing a GaAs single crystal by LEC Process, the shape of the interface between the solid phase and the liquid phase (solid-liquid interface) under the manufacturing the single crystal is made convex toward the melt side, the degree of convex of such shape (a ratio of the length T1, which is a distance from the interface between the melt and the liquid sealer to the top end of the crystal on the melt side, and the diameter of the single crystal T2, namely T1/T2) is made to be not smaller than 0.25, the crystal growth rate V1 in the direction along the crystal column on the solid-liquid interface is made to be 4 mm/hr to 7 mm/hr, and the crystal cooling rate after growth V2 is made to be −5° C./hr or lower. Thereby, a GaAs single crystal wafer is obtained, wherein the wafer has features such that, when the strain in the radial direction is expressed as Sr and the strain in the tangential direction on the circumference is expressed as St, the value of the residual stress in a wafer plane of the semi-insulating GaAs wafer denoted by |Sr−St| satisfies |Sr−St|<1.0×10⁻⁵ in the center area of wafer plane of the wafer and such that the wafer has such a region as satisfies |Sr−St|≧1.0×10⁻⁵ in the outer area of such wafer plane and has such a region as satisfies |Sr−St|<1.0×10⁻⁵ in the direction [011] in the outer area of such wafer plane. Therefore, combining the plane (001) and the direction [010], of which residual strains are high, with the direction [011], of which residual strain is small, lightens effects of the wafer bend and the degree of uniformity of temperature distribution in the wafer plane on the heat treatment in the device manufacturing process that uses GaAs single crystal wafer. Thus, the invented method realizes a large-size GaAs single crystal wafer having the feature stated above that generates no slipband even though the releasing of the residual stress by introduction of dislocation technique for elimination of occurrence of the slipband is not applied.

After manufacturing a semi-insulating GaAs single crystal as described in the embodiment of the present invention, the crystal is sliced to obtain a semi-insulating GaAs wafer substrate. On such wafer substrate, a thin film of compound semiconductor such as AlGaAs and InGaAs is formed by epitaxial growth using MOVPE Process or Molecular Beam Epitaxial Growth Method (MBE Process). After that processing, electronic devices or light receiving/emitting elements are manufactured using the wafer employing various techniques such as lithography and etching.

The lattice constant and the thermal expansion coefficient of thin film of compound semiconductors like AlGaAs and InGaAs grown by epitaxial growth are different from those of the base single crystal of GaAs because their compositions are different each from the other. On the other hand in the epitaxial growth in MOVPE Process, the process includes such a treatment as heats the wafer to about 800° C. to produce the epitaxial growth followed by cooling; this means that the wafer itself is exposed to a high temperature. Because of this thermal treatment, an epitaxial-grown GaAs single crystal wafer comes to have a high strain, which causes the wafer to bend into a convex shape as a whole. However, use of the semi-insulating GaAs single crystal wafer by the present invention as the substrate is able to reduce such bend.

The embodiment of the present invention indicates that it is practicable to provide a GaAs single crystal wafer having a large diameter of 150 mm or more that generates no slipband and a method of manufacturing the same. The invented method lightens effects of the wafer bend and the degree of nonuniformity of temperature distribution in the wafer plane on the heat treatment in the device manufacturing process that uses GaAs single crystal wafer and thereby the manufactured wafer generates no slipband even though the releasing of the residual stress by introduction of dislocation technique for elimination of occurrence of the slipband is not applied.

1. A GaAs single crystal wafer characterized
in that, when the strain in the radial direction in said GaAs single crystal wafer is expressed as Sr and the strain in the tangential direction on the circumference of the same is expressed as St,
the absolute value of the residual stress in a wafer plane of said wafer denoted by |Sr−St| is smaller than 1.0×10⁻⁵ in the center area of such wafer plane and
in that said wafer has such a region in which the value |Sr−St| is 1.0×10⁻⁵ or more in the outer area of such wafer plane and has such a region in which the value |Sr−St| is smaller than 1.0×10⁻⁵ in the direction [011] in said outer area of such wafer plane.

2. The GaAs single crystal wafer according to claim 1, wherein the dislocation density of said wafer in said wafer plane is 30,000 count/cm² or smaller.

3. The GaAs single crystal wafer according to claim 1, wherein the diameter of said wafer is 100 mm or more.

4. The GaAs single crystal wafer according to claim 2, wherein the diameter of said wafer is 100 mm or more.

5. The GaAs single crystal wafer according to claim 1, wherein the universal hardness of said outer area of said wafer plane is higher than that of said center area of said wafer plane and the universal hardness of said outer area of said wafer plane is higher than that in the direction [011] in said outer area of said wafer plane.

6. The GaAs single crystal wafer according to claim 5, wherein the universal hardness of any part of said wafer plane is 4000 N/mm² (MPa) or more and the universal hardness of said outer area of said wafer plane, except that of in the direction [011], is 4300 N/mm² (MPa) or more.

7. A method of manufacturing a GaAs single crystal, which is defined in claim 1, that uses a setup comprising
a crucible, which is mounted on a susceptor, being accommodated in a container and a melt of GaAs, which is melted by heat, and
a liquid sealer being contained in said crucible,
wherein said method applies a technique comprising the steps of
keeping a seed crystal kept touching the liquid phase of said melt of GaAs and
moving said seed crystal and said crucible relatively,
wherein the method is characterized in that
the shape of said solid phase on the solid-liquid interface between said solid phase and said liquid phase under the manufacturing said single crystal is made convex toward said liquid phase side,
the degree of convex of such shape
(a ratio of the length T1, which is the distance from said interface between said melt and said liquid sealer to the top end of said convex, and the diameter of said single crystal T2, namely T1/T2) is made to be 0.25 or more,
the crystal growth rate V1 in the direction of the relative movement on said solid-liquid interface is made to be 4 mm/hr to 7 mm/hr; and
the cooling rate V2 of said solid phase is made to be 5° C./hr or lower.
